(19) United States
(12) Patent Application Publication
(10) Pub. No.: US 2024/0421272 A1
(43) Pub. Date: Dec. 19, 2024

(54) DISPLAY DEVICE AND FABRICATING METHOD THEREOF

(71) Applicant: LG ELECTRONICS INC., Seoul (KR)

(72) Inventors: Hongkey PARK, Seoul (KR); Naree KIM, Seoul (KR); Hyunjong KIM, Seoul (KR); Dongkyu LEE, Seoul (KR); Jeongsik CHOI, Seoul (KR)

(73) Assignee: LG ELECTRONICS INC., Seoul (KR)

(21) Appl. No.: 18/734,962

(22) Filed: Jun. 5, 2024

(30) Foreign Application Priority Data
Jun. 13, 2023 (KR) 10-2023-0075748

(51) Int. Cl. H01L 33/58; H01L 25/16; H01L 33/52

(52) U.S. Cl. CPC H01L 33/58; H01L 25/167; H01L 33/52; H01L 2933/005; H01L 2933/0058

(57) ABSTRACT

The present disclosure is applicable to a display device related technical field and relates to a display device using a composite optical film and a light emitting element for example. The present disclosure may include a wiring substrate, an electrode pad partitioned on the wiring substrate, a multitude of light emitting elements forming a unit pixel by being connected to the electrode pad, an optical film layer forming a film on a multitude of the light emitting elements and including a filler, and an encapsulation layer positioned on the optical film layer.

Pursuant to 35 U.S.C. § 119 (a), this application claims the benefit of earlier filing date and right of priority to Korean Application No. 10-2023-0075748, filed on Jun. 13, 2023, the contents of which are all incorporated by reference herein in its entirety.

### BACKGROUND OF THE DISCLOSURE

### Field of the Disclosure

The present disclosure is applicable to a display device related technical field and relates to a display device using a composite optical film and a light emitting element for example.

### Discussion of the Related Art

Recently, a display device having excellent characteristics such as thinness and flexibility has been developed in the field of display technology.

A Light Emitting Diode (LED) is gradually miniaturized and used as a pixel of a display device.

Such a display device may be provided with a film that imparts an optical function. The film that imparts such an optical function may mainly serve as a black film that imparts a black color, and in addition, may impart functions such as anti-reflection and the like.

Meanwhile, such a film may perform a protective function of the display device. In order to implement various types of display devices or flexible display devices, flexibility of such a protective film may be required.

However, the optical properties of these films had limitations in imparting black color sense and preventing reflection as described above.

Additionally, a base film (CPI) has a multi-layered optical functional layer (e.g., black dye layer, anti-reflection layer (AG-AR), Anti-Finger (AF), etc.) in such a CPI-based film production process, which not only complicates the structure, but also requires a number of fabricating processes, thereby reducing the final quality.

Therefore, the need for measures to solve these problems is rising.

### SUMMARY OF THE DISCLOSURE

Accordingly, embodiments of the present disclosure are directed to a display device and fabricating method thereof that substantially obviate one or more problems due to limitations and disadvantages of the related art.

One technical task of the present disclosure is to provide a display device and fabricating method thereof, which minimize a distance between an optical film layer and an individual light emitting element forming a light source.

Another technical task of the present disclosure is to provide a display device and fabricating method thereof, where alleviate a whitening phenomenon caused by a filler as there is a relatively thick encapsulation layer with a black color on an optical film layer

Further technical task of the present disclosure is to provide a display device and fabricating method thereof, which provide excellent optical characteristics while forming a small number of layers.

Technical tasks obtainable from the present disclosure are non-limited by the above-mentioned technical tasks. And, other unmentioned technical tasks can be clearly understood from the following description by those having ordinary skill in the technical field to which the present disclosure pertains.

Additional advantages, objects, and features of the disclosure will be set forth in the disclosure herein as well as the accompanying drawings. Such aspects may also be appreciated by those skilled in the art based on the disclosure herein.

In a first aspect to achieve these objects and other advantages and in accordance with the purpose of the present disclosure, provided is a display device including a wiring substrate, an electrode pad partitioned on the wiring substrate, a multitude of light emitting elements forming a unit pixel by being connected to the electrode pad, an optical film layer forming a film on a multitude of the light emitting elements and including a filler, and an encapsulation layer positioned on the optical film layer.

A thickness of the optical film layer on each of top and side surfaces of each of a multitude of the light emitting elements may be smaller than a distance between the light emitting elements.

The optical film layer may have a same thickness on top and side surfaces of each of a multitude of the light emitting elements within an error range of 30%.

A thickness on a side surface of each of a multitude of the light emitting elements may be smaller than a distance between the light emitting elements.

The filler may include at least one of Zr, Si, Ti, Zn, BaS, or oxide thereof.

The encapsulation layer may include a black dye.

The encapsulation layer comprising the black dye may be positioned between a multitude of the light emitting elements.

The encapsulation layer may planarize unevenness formed by a shape of the light emitting element.

In a second aspect to achieve these objects and other advantages and in accordance with the purpose of the present disclosure, provided is a method of fabricating a display device, the method including forming a first optical film layer including a filler along a first column of a multitude of light emitting elements disposed on a wiring substrate and forming a second optical film layer including the filler along a second column of a multitude of the light emitting elements disposed on a wiring substrate, wherein a thickness of each of the first and second optical film layers on each of top and side surfaces of each of a multitude of the light emitting elements may be smaller than a distance between the light emitting elements.

The method may further include forming an encapsulation layer on the first and second optical film layers.

The first and second optical film layers may be formed to be distinguished from each other.

In a third aspect to achieve these objects and other advantages and in accordance with the purpose of the present disclosure, provided is a display device including a wiring substrate, first light emitting elements disposed along a first column on the wiring substrate, a first optical film layer positioned on the first light emitting elements and including a filler, second light emitting elements disposed along a second column on the wiring substrate, and a second optical film layer positioned on the second light emitting elements and including the filler, wherein a thickness of each of the first and second optical film layers on each of top and side surfaces of each of the first and second light emitting elements may be smaller than a distance between the light emitting elements.

Accordingly, the present disclosure provides various effects and/or advantages as follows.

First, according to one embodiment of the present disclosure, a distance between an optical film layer and an individual light emitting element constituting a light source may be minimized. Accordingly, the scattering effect of light may be improved. In addition, the possibility of deteriorating image quality due to the optical film layer may be reduced.

The optical film layer including an uneven surface has excellent adhesion to an encapsulation layer positioned thereon, so that the encapsulation layer may be a layer substantially forming an outermost surface of a display device.

Since the encapsulation layer contains a black dye such as a black resin, a separate black film may not be required.

For this reason, a scattering effect may be exhibited by a filler included in the optical film layer. Since an encapsulation layer having a relatively thick black color exists on the optical film layer, a whitening phenomenon due to the filler may be alleviated.

As described above, according to an embodiment of the present disclosure, it is possible to provide a display device having excellent optical characteristics while forming a small number of layers.

Furthermore, according to another embodiment of the present disclosure, other unmentioned effects can be clearly understood from the following description by those having ordinary skill in the technical field to which the present disclosure pertains.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. The above and other aspects, features, and advantages of the present disclosure will become more apparent upon consideration of the following description of preferred embodiments, taken in conjunction with the accompanying drawing figures. In the drawings:

FIG. 1 is a schematic cross-sectional diagram illustrating a display device according to one embodiment of the present disclosure;

FIG. 2 is a schematic cross-sectional diagram illustrating an optical film layer of a display device according to one embodiment of the present disclosure;

FIG. 3 is a schematic diagram illustrating a process of fabricating a display device according to one embodiment of the present disclosure;

FIG. 4 is a schematic cross-sectional diagram illustrating a process of fabricating a display device according to a comparative example;

FIG. 5 is an enlarged diagram showing a portion A shown in FIG. 4;

FIG. 6 is a schematic diagram illustrating a process of fabricating a display device according to a comparative example;

FIG. 7 is a conceptual diagram illustrating an example of an optical layer formed by a process of fabricating a display device according to a comparative example;

FIG. 8 is a schematic diagram illustrating a process of fabricating a display device according to one embodiment of the present disclosure;

FIG. 9 is a conceptual diagram illustrating an example of an optical layer formed by a process of fabricating a display device according to one embodiment of the present disclosure;

FIG. 10 is a graph illustrating a luminance distribution of a display device according to a comparative example; and

FIG. 11 is a graph illustrating a luminance distribution of a display device according to one embodiment of the present disclosure.

### DETAILED DESCRIPTION OF THE DISCLOSURE

Reference will now be made in detail to embodiments of the present disclosure, examples of which are illustrated in the accompanying drawings. Wherever possible, the same reference numbers will be used throughout the drawings to refer to the same or like parts, and redundant description thereof will be omitted. As used herein, the suffixes “module” and “unit” are added or used interchangeably to facilitate preparation of this specification and are not intended to suggest distinct meanings or functions. In describing embodiments disclosed in this specification, relevant well-known technologies may not be described in detail in order not to obscure the subject matter of the embodiments disclosed in this specification. In addition, it should be noted that the accompanying drawings are only for easy understanding of the embodiments disclosed in the present specification, and should not be construed as limiting the technical spirit disclosed in the present specification.

Furthermore, although the drawings are separately described for simplicity, embodiments implemented by combining at least two or more drawings are also within the scope of the present disclosure.

In addition, when an element such as a layer, region or module is described as being “on” another element, it is to be understood that the element may be directly on the other element or there may be an intermediate element between them.

The display device described herein is a concept including all display devices that display information with a unit pixel or a set of unit pixels. Therefore, the display device may be applied not only to finished products but also to parts. For example, a panel corresponding to a part of a digital TV also independently corresponds to the display device in the present specification. The finished products include a mobile phone, a smartphone, a laptop, a digital broadcasting terminal, a personal digital assistant (PDA), a portable multimedia player (PMP), a navigation system, a slate PC, a tablet, an Ultrabook, a digital TV, a desktop computer, and the like.

However, it will be readily apparent to those skilled in the art that the configuration according to the embodiments described herein is applicable even to a new product that will be developed later as a display device.

In addition, the semiconductor light emitting element mentioned in this specification is a concept including an LED, a micro LED, and the like, and may be used interchangeably therewith.

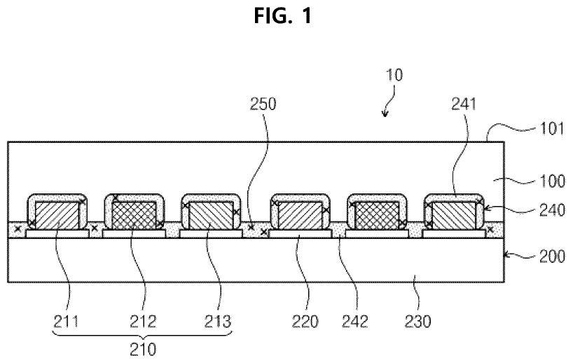

FIG. 1 is a schematic cross-sectional diagram illustrating a display device according to one embodiment of the present disclosure.

As shown in FIG. 1, a display device 10 includes a display panel 200. The display panel 200 may implement an image by a plurality of unit pixels 210 arranged on a substrate 230. An encapsulation layer 240 may be positioned on the unit pixel 210.

The display panel 200 may be a wiring substrate 200 including an electrode pad 220 to which the unit pixel 210 is connected. Hereinafter, the display panel 200 and the wiring substrate 200 may be used interchangeably.

The unit pixel 210 may include subpixels including a first sub-pixel 211, a second sub-pixel 212, and a third sub-pixel 213. Although two unit pixels 210 are illustrated in FIG. 1, which is schematically illustrated, and it is obvious that more unit pixels 210 may be configured on the wiring substrate 200.

The first sub-pixel 211, the second sub-pixel 212, and the third sub-pixel 213 may be a red light emitting element 211, a green light emitting element 212, and a blue light emitting element 213, respectively. That is, each of the individual sub-pixels 211, 212, and 213 may be implemented by a light emitting element. Hereinafter, the sub-pixels 211, 212, and 213 may be used interchangeably with the light emitting elements 211, 212, and 213.

As an exemplary embodiment, an optical film layer 240 may be positioned on each of the light emitting elements 211, 212, and 213. The optical film layer 240 may form a film on a plurality of the light emitting elements 211, 212, and 213. For example, the optical film layer 240 may form a thin layer (i.e., a film) along outer surfaces of a plurality of light emitting elements 211, 212, and 213.

The optical film layer 240 may include a film layer 241 positioned on the outer surfaces of the light emitting elements 211, 212, and 213 and a connection layer 242 positioned between the light emitting elements 211, 212, and 213.

For example, the film layer 241 of the optical film layer 240, which is a film positioned on the outer surfaces of the light emitting elements 211, 212, and 213, may have a thickness smaller than a distance between the light emitting elements 211, 212, and 213 on top and side surfaces of the individual light emitting elements 211, 212, and 213. Accordingly, the film layer 241 may be formed along the shape of the outer surfaces of the individual light emitting elements 211, 212, and 213. That is, the film layer 241 may maintain the shape of the outer surfaces of the individual light emitting elements 211, 212, and 213. For example, the thickness of the optical film layer 240 including the film layer 241 on the side surfaces of the individual light emitting elements 211, 212, and 213 may be smaller than the distance between the individual light emitting elements 211, 212, and 213.

As an exemplary embodiment, the optical film layer 240 may have substantially the same thickness on the top and side surfaces of the individual light emitting elements 211, 212, and 213. Here, the term “substantial” may mean a thickness formed while maintaining the shape of the outer surfaces of the individual light emitting elements 211, 212, and 213 along the outer surfaces of the individual light emitting elements 211, 212, and 213. For example, the optical film layer 240 may have the same thickness within a 30% error range on the top and side surfaces of the individual light emitting elements 211, 212, and 213.

As an exemplary embodiment, the optical film layer 240 may include a filler 250. The filler 250 may include a light scattering agent. For example, the filler 250 may be a light scattering agent. The light scattering agent 250 may include at least one of Zr, Si, Ti, Zn, BaS, and oxides thereof.

The encapsulation layer 100 may be positioned on the optical film layer 240.

In an exemplary embodiment, the encapsulation layer 100 may include a black dye.

The encapsulation layer 100 may be positioned between a plurality of individual light emitting elements 211, 212, and 213. For example, the encapsulation layer 100 including a black dye may be positioned between individual light emitting elements 211, 212, and 213.

The encapsulation layer 100 may planarize irregularities formed by the shapes of the individual light emitting elements 211, 212, and 213. As described above, the shapes of the individual light emitting elements 211, 212, and 213 may be maintained in a state in which the optical film layer 240 is coated. Accordingly, the encapsulation layer 100 may planarize the shapes of the individual light emitting elements 211, 212, and 213.

The encapsulation layer 100 is formed of an insulating and flexible material such as polyimide (PI), PET, PEN, and the like, and may be integrally formed with the wiring substrate 200 to form a single substrate. As described above, the substrate 230 provided with the electrode pad 220 may be a wiring substrate on which a wiring electrode (not shown) is connected to the electrode pad 220. Hereinafter, the substrate 230 is the wiring substrate 230 for example, and the substrate and the wiring substrate will be described by using the same reference numeral.

The filler 250 included in the optical film layer 240 may have the property of refracting or scattering light emitted from the light emitting element 210. Alternatively, the filler 250 may have the property of refracting or scattering light incident from the outside of the display device 10.

The light emitted from the light emitting elements 211, 212, and 213 may be refracted and/or scattered in the filler 250. The light scattered in the filler 250 may be emitted to the outside of the optical film layer 240 and the encapsulation layer 100.

At least one of the optical film layer 240 and the encapsulation layer 100 may have light transmittance. For example, the encapsulation layer 100 cured by including silicon may have a refractive index of 1.4 to 1.6. Accordingly, light may be totally reflected inside the encapsulation layer 100. The filler 250 may refract or scatter the light totally reflected inside the encapsulation layer 100.

That is, the filler 250 may act as a light scattering agent. Therefore, the filler 250 may be referred to as a light scattering agent. In the following description, the filler and the light scattering agent may mean the same entity.

For example, the filler 250 may be spherical or amorphous. Also, a diameter or size of the filler 250 may be in a range of 10 nanometers (nm) to 10 micrometers (μm). A content (weight ratio) of the filler 250 may be 0.01% to 30% with respect to the optical film layer 240.

For example, the filler 250 may contain Zr oxide. Also, for example, the filler 250 may contain Si oxide.

In some cases, two types of fillers 250 having different characteristics may be included in the optical film layer 240. In this case, optical characteristics of the two types of fillers 250 may be different from each other. As mentioned above, the optical characteristic may be a characteristic of refracting or scattering light emitted from the light emitting element 210.

The light scattering agent 250 may interfere with straightness of light emitted from a light source (e.g., light emitting element) forming the unit pixel 211, 212, and 213, thereby causing light scattering that is a kind of random reflection. Accordingly, the light scattering agent 250 may prevent a luminance deviation phenomenon in which light emitted from the unit pixel 211, 212, and 213 is biased in a specific direction.

In addition, the light scattering agent 250 may improve a phenomenon in which color looks different depending on a left/right position and angle based on the position of the substrate 230 (e.g., a phenomenon in which reduction in luminance is not uniform).

When the above light scattering agent 250 is used, the scattering effect may be increased and a high-content filler (e.g., a light scattering agent) may be added.

As an exemplary embodiment, the display panel 200 may be a flexible display.

The flexible display may include, for example, a display that can be bent, curved, twisted, or folded by an external force.

Furthermore, the flexible display may include, for example, a display fabricated on a thin and flexible substrate that can curve, bend, fold, or roll like paper while maintaining the display characteristics of an existing flat panel display.

In a state in which the flexible display is not bent (e.g., a state having an infinite radius of curvature, hereinafter referred to as a first state), a display area of the flexible display becomes a flat surface. In a state of being bent by an external force in the first state (e.g., a state having a finite radius of curvature, hereinafter referred to as a second state), the display area may become a uneven surface. Information displayed in the second state may become visual information outputted on the uneven surface. Such visual information may be implemented by independently controlling light emission of a unit pixel (i.e., subpixels) arranged in a matrix form. Here, the unit pixel (i.e., subpixels) may mean, for example, a minimum unit for implementing one color.

As described above, the unit pixel of the display panel 200 may be implemented by a light emitting element. In one embodiment of the present disclosure, a Light Emitting Diode (LED) is exemplified as a kind of a semiconductor light emitting element that converts current into light. The light emitting diode is formed to have a small size, and in the case of a flexible display, may serve as a unit pixel even in the second state.

The substrate 230 may include glass or polyimide (PI). In order to implement a flexible display, the substrate 230 may use any material with insulating and flexible properties, for example, polyethylene naphthalate (PEN), polyethylene terephthalate (PET), etc. Also, the substrate 230 may include any transparent or opaque material.

The encapsulation layer 100 may be disposed on the substrate 230. The encapsulation layer 100 includes an insulating and flexible material such as polyimide (PI), PET, PEN, etc., and may be integrally formed with the substrate 230 to form a single substrate.

A wiring electrode (not shown) to which the light emitting elements respectively forming unit subpixels 211, 212, and 213 are connected may be provided on the substrate 230. Hereinafter, as one embodiment, a unit pixel may have the same meaning as a light emitting element. Therefore, description will be made using the same reference numbers. For example, three unit subpixels may form one pixel. That is, the red (R) light emitting element 211, the green light emitting element 212, and the blue light emitting element 213 may form one pixel. As described above, the light emitting element may include a semiconductor Light Emitting Diode (LED).

The semiconductor light emitting element 211, 212, or 213 forming the unit pixel may be a micro LED having a size of several to several hundreds of micrometers. In some cases, the semiconductor light emitting element 211, 212, or 213 may be a mini LED having a size several tens of times greater than that of the micro LED. Here, the mini LED may differ from the micro LED in a size and stack structure. Specifically, the mini LED may further include a growth substrate for growing a semiconductor layer.

As an example of the semiconductor light-emitting elements 211, 212, and 213 forming the unit subpixels, micro LEDs or mini LEDs may have a stacked LED form consisting of red (R), green (G), and blue (B) layers in a single LED as well as a form in which red (R), green (G), and blue (B) LEDs emit light independently.

Although not shown, a Thin Film Transistor (TFT) may be connected to the wiring electrode to implement an Active Matrix (AM) type display device. For one example, the substrate 230 may include a TFT substrate. For another example, the substrate 230 may include a substrate of a Passive Matrix (PM) type.

In FIG. 1, the structure of the display panel 200 is simplified to be shown schematically. A detailed configuration of the display panel 200 will be omitted in the following description.

As mentioned above, the composite optical film 100 may be positioned on the display panel 200.

In some cases, on the encapsulation layer 100, a transparent adhesive layer, an anti-reflective layer including a light scattering pattern, and other optical functional layers may be included. The optical functional layer may include at least one of a Low Reflection (LR) film and an Anti-Fingerprint (AF) film.

The encapsulation layer 100 including the black dye is a black dye having a preset transmittance, and may have a transmittance of 10% to 60%. In this case, the encapsulation layer 100 may include a ultraviolet blocking agent to increase the ultraviolet blocking effect. The encapsulation layer 100 may perform a function of increasing a contrast ratio. In addition, the encapsulation layer 100 may alleviate a whitening phenomenon due to the filler 250.

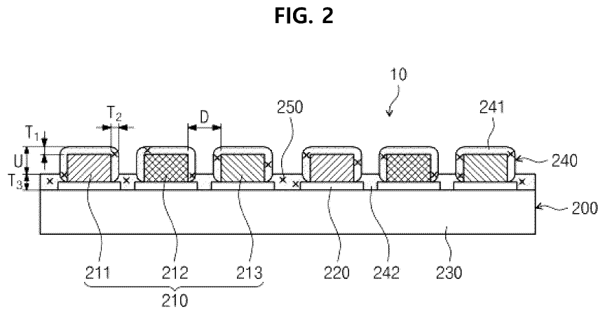

FIG. 2 is a schematic cross-sectional diagram illustrating an optical film layer of a display devices according to one embodiment of the present disclosure.

As described above with reference to FIG. 1, as an exemplary embodiment, an optical film layer 240 may be positioned on each of light emitting elements 211, 212, and 213. The optical film layer 240 may form a film on a plurality of the light emitting elements 211, 212, and 213. For example, the optical film layer 240 may form a thin layer (i.e., a film) along outer surfaces of a plurality of the light emitting elements 211, 212, and 213.

The optical film layer 240 may include a film layer 241 positioned on the outer surfaces of the light emitting elements 211, 212, and 213 and a connection layer 242 positioned between the light emitting elements 211, 212, and 213.

For example, the optical film layer 240 may have a thickness less than a distance between the light emitting elements 211, 212, and 213 on top and side surfaces of each of the light emitting elements 211, 212, and 213.

For example, in the optical film layer 240, at least one of a thickness T1 located on the top surface of each of the light emitting elements 211, 212, and 213 and a thickness T2 located on the side surface of each of the light emitting elements 211, 212, and 213 may have a thickness less than a distance D between the light emitting elements 211, 212, and 213.

As an exemplary embodiment, in the optical film layer 240 on each of the light emitting devices 211, 212, and 213, the thickness T1 on the top surface and the thickness T2 on the side surface may be substantially the same. Here, the term ‘substantially’ may mean a thickness formed along the outer surface of each of the light emitting devices 211, 212, and 213 while maintaining the shape of the outer surface of each of the light emitting devices 211, 212, and 213. In this case, a height U of the outer surface of each of the light emitting devices 211, 212, and 213 may correspond to a height resulting from adding the thickness T1 of the optical film layer 240 on the top surface of each of the light emitting devices 211, 212, and 213 to a height of the light emitting element.

For example, in the optical film layer 240 on each of the light emitting devices 211, 212, and 213, the thickness T1 on the top surface and the thickness T2 on the side surface may be within an error range of 50%. For another example, in the optical film layer 240 on each of the light emitting devices 211, 212, and 213, the thickness T1 on the top surface and the thickness T2 on the side surface may be within an error range of 30%. For further example, in the optical film layer 240 on each of the light emitting devices 211, 212, and 213, the thickness T1 on the top surface and the thickness T2 on the side surface may be within an error range of 15%.

For example, a thickness T3 of the connection layer 242 positioned between the light emitting elements 211, 212, and 213 may be similar to the thickness T1 of the optical film layer 240 on the top surface of each of the light emitting elements 211, 212, and 213.

As described above, a filler 250 may be distributed within a range of the thickness T1 on the top surface and the thickness T2 on the side surface in the optical film layer 240 on each of the light emitting devices 211, 212, and 213 and the thickness T3 of the connection layer 242.

An encapsulation layer 100 may be positioned on the optical film layer 240. For example, an outer surface 101 of the encapsulation layer 100 may be polished to form a smooth surface.

Unevenness may exist on an outer side surface of the optical film layer 240. For example, fine natural unevenness may exist on the outer side surface of the optical film layer 240.

The optical film layer 240 including the uneven surface thinly surrounds each of the light emitting elements 211, 212, and 213, so that a distance between the optical film layer 240 and each of the light emitting elements 211, 212, and 213 forming the light source may be minimized. Accordingly, a scattering effect of light may be improved. Also, the possibility of image quality deterioration due to the optical film layer 240 may be reduced.

The optical film layer 240 including the uneven surface has excellent adhesion to the encapsulation layer 100 positioned thereon, so that the encapsulation layer 100 may become a layer substantially forming an outermost surface of the display device 10.

The encapsulation layer 100 may have a thickness of approximately 200 to 300 micrometers (μm). Since the encapsulation layer 100 contains a black dye such as a black resin, a separate black film may not be required.

For this reason, a scattering effect may be exhibited by the filler 250 included in the optical film layer 240. Since the encapsulation layer 100 having a relatively thick black color exists on the optical film layer 240, a whitening phenomenon due to the filler 250 may be alleviated.

As described above, according to one embodiment of the present disclosure, it is possible to provide a display device 10 having excellent optical characteristics while forming a small number of layers.

On the other hand, the optical film layer 240 forming the film has the effect of gathering the filler 250 to a necessary part, thereby reducing the total amount of scattering agent used.

In addition, there is no need to attach a black film additionally using a thick black resin layer, so an unnecessary film attachment process can be removed.

Accordingly, since there is no thick black resin layer and film, the color deviation between the light emitting elements may not depend on the color deviation of the optical film. This may play a large role in increasing image quality in fabricating a display device using light emitting elements.

Meanwhile, an L value (e.g., a black/white value) may be improved. In comparison with the comparative example described below, the value may be improved to a value between approximately 15 and 3 to 9.

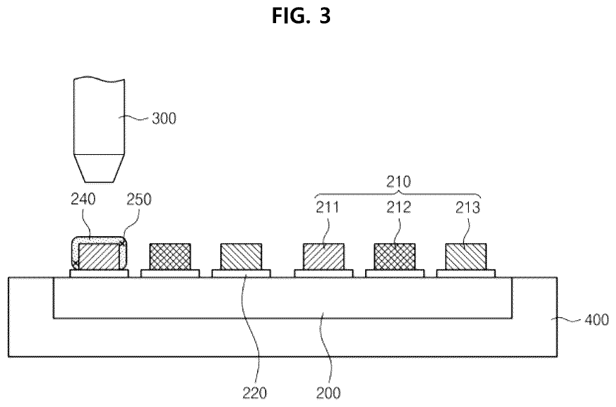

FIG. 3 is a schematic diagram illustrating a process of fabricating a display device according to one embodiment of the present disclosure.

Referring to FIG. 3, a process of fabricating a display device provided with a composite optical film according to one embodiment of the present disclosure may be performed using a jetting process for forming an optical film layer 240 after being placed on a support 400 while a unit pixel 210 is provided on a wiring substrate 200.

For example, by coating a resin for forming the optical film layer 240 including a filler 250 using a nozzle 300, a film layer 241 positioned on outer surfaces of light emitting elements 211, 212, and 213 maybe formed. Subsequently, a jetting process is performed in a manner of moving a nozzle 300 moves to a neighboring light emitting element 212, so that the film layer 241 may be formed on the neighboring element. In addition, a connection layer 242 (see FIGS. 1 and 2) positioned between the light emitting elements 211, 212, and 213 may be formed.

In this case, the optical film layer 240 including the film layer 241 and the connection layer 242 may have the structure shown in FIG. 1 and FIG. 2. Here, redundant descriptions are omitted.

Thereafter, the resin for forming the optical film layer 240 may be cured.

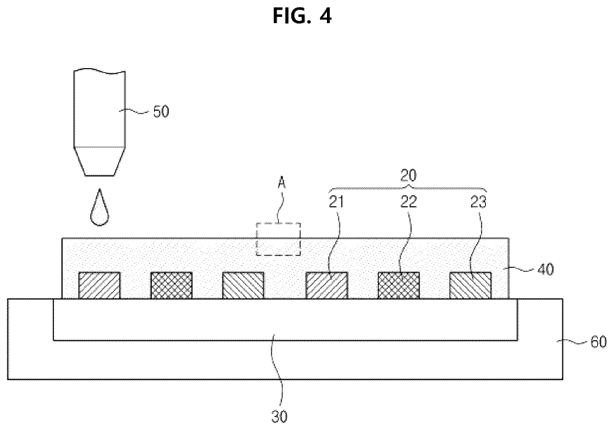

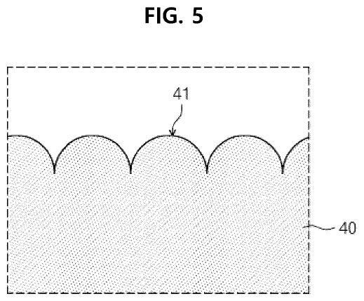

FIG. 4 is a schematic cross-sectional view illustrating a process of fabricating a display device according to a comparative example. FIG. 5 is an enlarged view of a portion A shown in FIG. 4.

Referring to FIG. 4, a process of fabricating a display device provided with a composite optical film according to a comparative example may be performed using a jetting process for forming an optical layer 40 after a unit pixel 20 is placed on a support 60 while the unit pixel 20 is provided on a wiring substrate 30. For example, a resin for forming the optical layer 40 is applied using a nozzle 50.

In this case, the jetting process may be performed to form a thick optical layer 40 covering the entire unit pixel 20.

Referring to FIG. 5, the optical layer 40 formed by the jetting process may form an uneven surface 41. Accordingly, to form an additional film later, a process for smoothing the uneven surface 41 may be added.

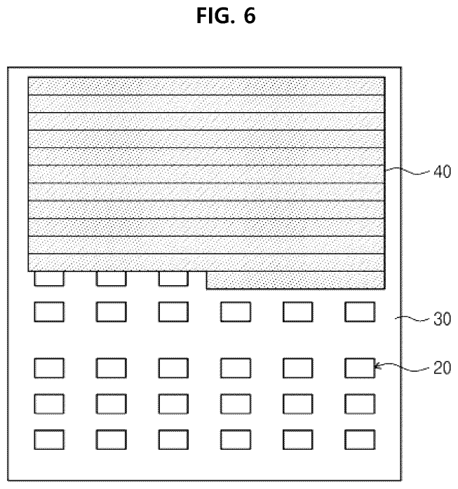

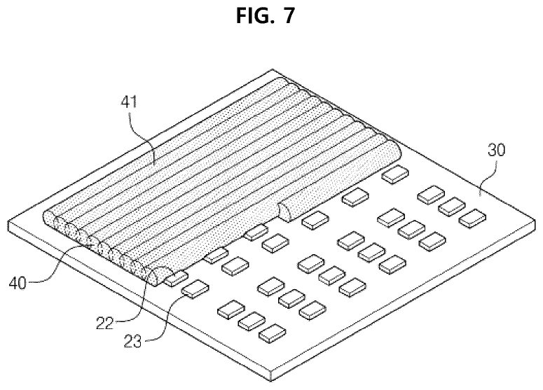

FIG. 6 is a schematic diagram illustrating a process of fabricating a display device according to a comparative example. FIG. 7 is a conceptual diagram illustrating an example of an optical layer formed by a process of fabricating a display device according to a comparative example.

According to a jetting process based on such a comparative example, first, a liquid resin (e.g., silicon) may be applied onto a substrate 30 using a nozzle 50.

Thereafter, the resin (e.g., silicon) may be solidified by thermosetting.

According to the jetting process, an upper surface of the resin (e.g., silicon) is not flat and may have an uneven shape, which is because the liquid silicon is coated while the nozzle 50 is moving.

Therefore, a process of flattening an upper surface 41 of an optical layer 40 by wrapping is required, and a cleaning process of cleaning the wrapped portion is required afterwards.

Referring to FIG. 7, the resin forming the optical layer 40 is formed by covering the entire individual light emitting elements 22 and 23 so that a gap between the individual light emitting elements 22 and 23 is not revealed.

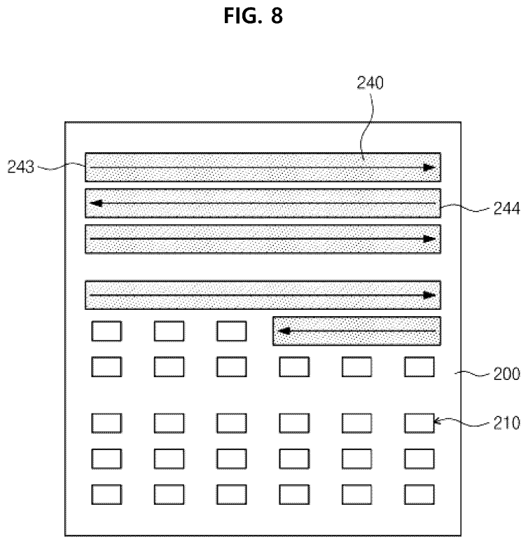

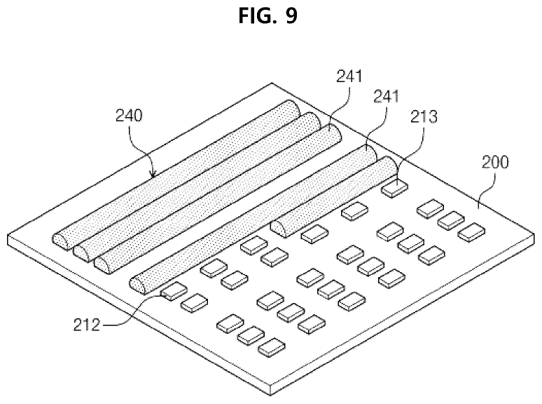

FIG. 8 is a schematic diagram illustrating a process of fabricating a display device according to one embodiment of the present disclosure. FIG. 9 is a conceptual diagram illustrating an example of an optical layer formed by a process of fabricating a display device according to one embodiment of the present disclosure.

Referring to FIG. 8, a process of fabricating a display device according to one embodiment of the present disclosure may include a step of forming a first optical film layer 243 including a filler 250 along a first column of a multitude of light emitting elements 210 disposed on a wiring substrate 200 and a step of forming a second optical film layer 244 including a filler 250 along a second column of a multitude of the e light emitting elements 210.

In the step of forming the first optical film layer 243 and the step of forming the second optical film layer 244, a liquid resin (e.g., silicon) may be coated or applied onto the wiring substrate 200 by a jetting process using a nozzle 300 (see FIG. 3).

In this case, each of the first optical film layer 243 and the second optical film layer 244 may have a thickness on top and side surfaces of the individual light emitting element 210, which is smaller than a distance between the light emitting elements 210. For example, the first optical film layer 243 and the second optical film layer 244 may be formed to be distinguished from each other.

In an exemplary embodiment, thereafter, a step of forming an encapsulation layer 100 (see FIG. 1 and FIG. 2) on the first optical film layer 243 and the second optical film layer 244 may be performed.

Referring to FIG. 9, the resin forming the optical film layer 240 may be formed to form a film that reveals a gap between the individual light emitting devices 212 and 21.

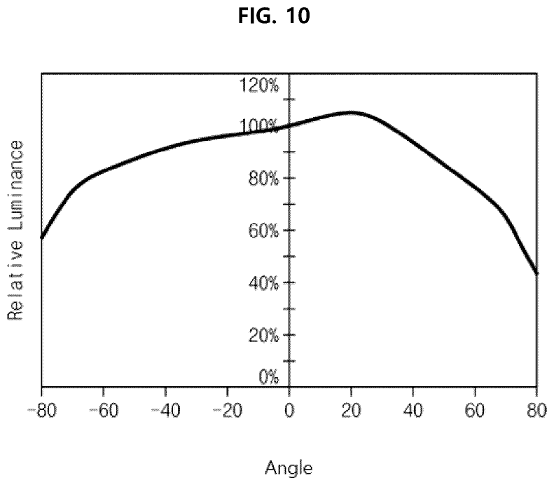

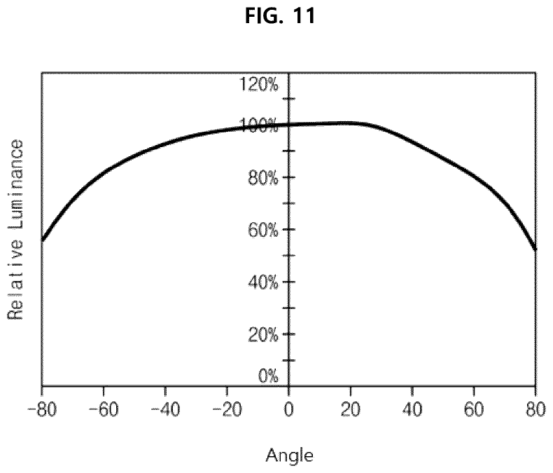

FIG. 10 is a graph illustrating luminance distribution of a display device according to a comparative example. FIG. 11 is a graph illustrating luminance distribution of a display device according to an embodiment of the present disclosure.

Referring to FIG. 10 and FIG. 11, it may be seen that the luminance change at the left and right viewing angles is uniformly improved in a display device according to one embodiment of the present disclosure.

In this way, as the luminance change becomes uniform according to the viewing angle, an image quality of a display may be improved.

As described above, the optical film layer 240 includes the filler (e.g., the light scattering agent 250) so that Haze may be improved. In addition, light extraction efficiency may be increased.

For example, silicon has a refractive index of 1.53, silicon oxide (SiO₂), an example of a filler (e.g., scattering agent), has a refractive index of 1.45, and air has a refractive index of 1.0.

In this case, the total internal reflection generated inside the silicon and at the air interface can be reduced owing to random light scattering by the silicon oxide (SiO₂), thereby improving light extraction efficiency of a front surface of the display.

Features, structures, effects, and the like described in the above embodiments are included in at least one embodiment of the present disclosure and are not necessarily limited to one embodiment. Furthermore, the features, structures, effects, and the like illustrated in each embodiment may be combined or modified with other embodiments by those skilled in the art to which the embodiments pertain. Therefore, the contents related to such combinations and modifications should be construed as being included in the scope of the present disclosure.

In addition, although the above description is made centering on the embodiments, this is only exemplary and non-limits the present disclosure, and those skilled in the art to which the present disclosure pertains will appreciate that various modifications and applications not illustrated above are possible without departing from the essential characteristics of the present embodiment. For example, each component specifically shown in the embodiment may be modified and implemented. And, differences related to these modifications and applications should be construed as being included in the scope of the present disclosure specified in the accompanying claims.

What is claimed is:

1. A display device, comprising:
a wiring substrate;
an electrode pad partitioned on the wiring substrate;
a multitude of light emitting elements forming a unit pixel by being connected to the electrode pad;
an optical film layer forming a film on a multitude of the light emitting elements and including a filler; and
an encapsulation layer positioned on the optical film layer.

2. The display device of claim 1, wherein a thickness of the optical film layer on each of top and side surfaces of each of a multitude of the light emitting elements is smaller than a distance between the light emitting elements.

3. The display device of claim 1, wherein the optical film layer has a same thickness on top and side surfaces of each of a multitude of the light emitting elements within an error range of 30%.

4. The display device of claim 1, wherein a thickness on a side surface of each of a multitude of the light emitting elements is smaller than a distance between the light emitting elements.

5. The display device of claim 1, wherein the filler comprises at least one of Zr, Si, Ti, Zn, BaS, or oxide thereof.

6. The display device of claim 1, wherein the encapsulation layer comprises a black dye.

7. The display device of claim 6, wherein the encapsulation layer comprising the black dye is positioned between a multitude of the light emitting elements.

8. The display device of claim 1, wherein the encapsulation layer planarizes unevenness formed by a shape of the light emitting element.

9. A method of fabricating a display device, the method comprising:
forming a first optical film layer including a filler along a first column of a multitude of light emitting elements disposed on a wiring substrate; and
forming a second optical film layer including the filler along a second column of a multitude of the light emitting elements disposed on a wiring substrate,
wherein a thickness of each of the first and second optical film layers on each of top and side surfaces of each of a multitude of the light emitting elements is smaller than a distance between the light emitting elements.

10. The method of claim 9, wherein the first and second optical film layers have a same thickness on the top and side surfaces of each of a multitude of the light emitting elements within an error range of 30%.

11. The method of claim 9, wherein the filler comprises at least one of Zr, Si, Ti, Zn, BaS, or oxide thereof.

12. The method of claim 9, further comprising forming an encapsulation layer on the first and second optical film layers.

13. The method of claim 12, wherein the encapsulation layer comprises a black dye.

14. The method of claim 12, wherein the encapsulation layer planarizes unevenness formed by a shape of the light emitting element.

15. The method of claim 9, wherein the first and second optical film layers are formed to be distinguished from each other.

16. A display device, comprising:
a wiring substrate;
first light emitting elements disposed along a first column on the wiring substrate;
a first optical film layer positioned on the first light emitting elements and including a filler;
second light emitting elements disposed along a second column on the wiring substrate; and
a second optical film layer positioned on the second light emitting elements and including the filler,
wherein a thickness of each of the first and second optical film layers on each of top and side surfaces of each of the first and second light emitting elements is smaller than a distance between the light emitting elements.

17. The display device of claim 16, wherein the first and second optical films have a same thickness on the top and side surfaces of each of the first and second light emitting elements within an error range of 30%.

18. The display device of claim 16, wherein the filler comprises at least one of Zr, Si, Ti, Zn, BaS, or oxide thereof.

19. The display device of claim 16, further comprising an encapsulation layer positioned on the first and second optical film layers.

20. The display device of claim 19, wherein the encapsulation layer planarizes unevenness formed by a shape of each of a multitude of the light emitting elements.
